(19) United States
(12) Patent Application Publication
(10) Pub. No.: US 2025/0218746 A1
(43) Pub. Date: Jul. 3, 2025

(54) APPARATUS FOR AND METHOD OF PROCESSING SUBSTRATE

(71) Applicant: SEMES CO., LTD., Cheonan-si (KR)

(72) Inventor: In Hee KANG, Yongin-si (KR)

(21) Appl. No.: 18/910,005

(22) Filed: Oct. 9, 2024

(30) Foreign Application Priority Data
Dec. 29, 2023 (KR) 10-2023-0195991

(51) Int. Cl. H01J 37/32; H01L 21/683

(52) U.S. Cl. CPC H01J 37/32697; H01J 37/32183; H01J 37/32715; H01J 37/32935; H01L 21/6833

(57) ABSTRACT

An apparatus and method of processing a substrate are provided. The apparatus for processing a substrate includes a chamber having a processing space therein, an electrostatic chuck supporting a substrate within the chamber, a plasma generating unit generating plasma in the processing space, a first voltage application unit applying a first voltage to the electrostatic chuck, a second voltage application unit applying a second voltage to the electrostatic chuck, and a compensation unit calculating a compensation value for the second voltage based on a measurement value of a sensor disposed in the first voltage application unit, and compensating for loss of chucking force generated in the electrostatic chuck based on the compensation value for the second voltage.

### CROSS-REFERENCE TO RELATED APPLICATION(S)

This application claims benefit of priority to Korean Patent Application No. 10-2023-0195991 filed on Dec. 29, 2023 in the Korean Intellectual Property Office, the disclosure of which is incorporated herein by reference in its entirety.

### BACKGROUND

### 1. Field

The present disclosure relates to an apparatus for and a method of processing a substrate.

### 2. Description of Related Art

Plasma refers to matter in a gaseous state separated into ions, radicals, electrons, and the like at high temperatures. Plasma is generated by very high temperatures, strong electric fields, or RF electromagnetic fields.

A semiconductor device manufacturing process may include a process of etching the surface of a substrate to form a required pattern on the substrate. The etching process may be performed by ions or radicals contained in the plasma, colliding with or reacting with a thin film formed on the substrate.

A plasma sheath refers to the area between the plasma bulk and the substrate, and is caused by a difference in a movement speed of electrons and ions. Since positive ions are relatively densely packed in the sheath, a phenomenon of a sudden voltage drop may occur inside the sheath.

The voltage drop inside the sheath affects an electrostatic chuck fixing the substrate, which causes the substrate's mounting position to change during the process or the fixing state of the substrate to become unstable. In detail, there is a risk that the accuracy of substrate processing may be reduced due to the voltage drop inside the sheath during an ultra-fine process.

### SUMMARY

An aspect of the present disclosure is to provide an apparatus for and a method of processing a substrate, in which a loss of chucking force of an electrostatic chuck due to voltage drop inside a sheath may be compensated.

An aspect of the present disclosure is to provide an apparatus for and a method of processing a substrate, in which loss of chucking force of an electrostatic chuck due to voltage drop inside a sheath may be approximated with a DC bias value and the DC bias value may be derived based on a measurement value of a sensor connected to an output terminal of a bias matcher that applies a bias voltage to the electrostatic chuck.

An aspect of the present disclosure is to provide an apparatus for and a method of processing a substrate, in which risk of the substrate's mounting position changing for each substrate processing process or each process step may be prevented and accuracy of the process may be improved.

According to an aspect of the present disclosure, the following apparatus for processing a substrate and method of processing a substrate are provided.

According to an aspect of the present disclosure, an apparatus for processing a substrate includes a chamber having a processing space therein, an electrostatic chuck supporting a substrate within the chamber, a plasma generating unit generating plasma in the processing space, a first voltage application unit applying a first voltage to the electrostatic chuck, a second voltage application unit applying a second voltage to the electrostatic chuck, and a compensation unit calculating a compensation value for the second voltage based on a measurement value of a sensor disposed in the first voltage application unit, and compensating for loss of chucking force generated in the electrostatic chuck based on the compensation value for the second voltage.

According to an aspect of the present disclosure, a method of processing a substrate includes generating plasma in a processing space within a chamber, applying a first voltage to an electrostatic chuck supporting a substrate within the chamber, applying a second voltage to the electrostatic chuck, obtaining a measurement value of a sensor for a first voltage application unit applying the first voltage, calculating a compensation value for the second voltage based on the measurement value of the sensor, and compensating for loss of chucking force of the electrostatic chuck based on the compensation value for the second voltage.

According to an aspect of the present disclosure, an apparatus for processing a substrate includes a chamber having a processing space therein, a substrate support member including an electrostatic chuck supporting a substrate and adsorbing the substrate, within the chamber, a plasma generation unit supplying processing gas to the processing space and generating plasma from the processing gas, a bias voltage application unit including a bias voltage generator generating a bias voltage and applying the bias voltage to a first electrode of the electrostatic chuck, a DC voltage application unit including a DC voltage generator generating a DC voltage and applying the DC voltage to a second electrode of the electrostatic chuck, and a compensation unit calculating a compensation value for the DC voltage, based on a measurement value of a sensor disposed in the bias voltage application unit, and compensating for loss of chucking force for adsorbing the substrate by the electrostatic chuck based on the compensation value for the DC voltage.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 illustrates an apparatus for processing a substrate according to an embodiment;

FIG. 2 is an example diagram illustrating a voltage drop inside a sheath;

FIG. 3 is a block diagram illustrating a portion of an apparatus for processing a substrate according to an embodiment;

FIG. 4 is a schematic diagram illustrating a portion of an apparatus for processing a substrate according to an embodiment;

FIG. 5A is a graph illustrating potentials by position of an apparatus for processing a substrate according to a comparative example;

FIG. 5B is a graph illustrating potentials by position of an apparatus for processing a substrate according to an embodiment; and

FIG. 6 is a flowchart of a method of processing a substrate according to an embodiment.

### DETAILED DESCRIPTION

Hereinafter, with reference to the attached drawings, embodiments will be described in detail so that those skilled in the art may easily practice the present disclosure. However, when describing example embodiments of the present disclosure in detail, if it is determined that a detailed description of related known functions or configurations may unnecessarily obscure the gist of the present disclosure, the detailed description thereof will be omitted. In addition, the same symbols are used throughout the drawings for parts that perform similar functions and actions. In addition, in this specification, the terms ‘on,’ ‘upper portion,’ ‘upper surface,’ ‘below,’ ‘lower portion,’ ‘lower surface,’ ‘lower side,’ ‘side,’ ‘side surface’, and the like are based on the drawings, and in reality, may vary depending on the direction in which the elements or components are disposed.

In addition, throughout the specification, when a part is said to be ‘connected’ to another part, this includes not only cases in which it is ‘directly connected’, but also cases in which it is ‘indirectly connected’ with another element therebetween. In addition, ‘including’ a certain component means that other components may be included, rather than excluding other components, unless otherwise specifically stated.

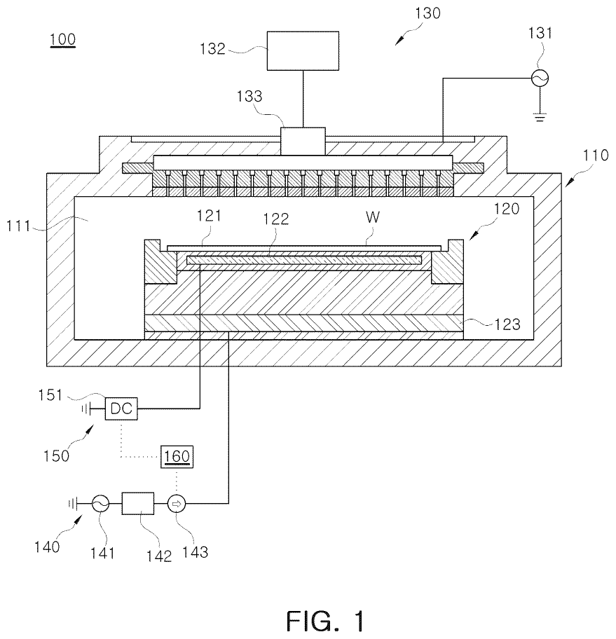

FIG. 1 illustrates an apparatus for processing a substrate according to an embodiment. Referring to FIG. 1, an apparatus 100 for processing a substrate may include a chamber 110, an electrostatic chuck 120, a plasma generation unit 130, a first voltage application unit 140, a second voltage application unit 150, and a compensation unit 160.

The apparatus 100 for processing a substrate may perform processing on a substrate (W) using plasma. The processing on the substrate (W) may include, for example, an etching process.

A processing space 111 may be formed inside the chamber 110. The processing space 111 may be provided as a space in which processing on the substrate (W) is performed. The processing space 111 may be an environment that may be controlled with an appropriate temperature and pressure to perform processing on the substrate (W).

An electrostatic chuck 120 may be placed inside the chamber 110. The electrostatic chuck 120 may include a substrate support surface 121. The substrate support surface 121 may support a substrate (W) and adsorb and fix the substrate (W).

The electrostatic chuck 120 may include a DC electrode 122 and a bias electrode 123. The electrostatic chuck 120 may fix the substrate (W) or control the processing performed on the substrate (W) by applying voltage to at least one of the DC electrode 122 and the bias electrode 123.

In addition, the electrostatic chuck 120 may be controlled to have a set temperature to control the processing of the substrate (W).

The plasma generation unit 130 may generate plasma in the processing space 111. The plasma generation unit 130 may include a voltage application unit 131, a processing gas supply unit 132, and a processing gas inlet unit 133.

The processing gas supply unit 132 may supply processing gas to the processing space 111 through the processing gas inlet unit 133. The voltage application unit 131 may apply a high-frequency voltage to an upper electrode located in the upper portion of the chamber 110.

The first voltage application unit 140 may be electrically connected to the bias electrode 123 of the electrostatic chuck 120. The first voltage application unit 140 may apply the first voltage to the bias electrode 123 of the electrostatic chuck 120.

For example, the first voltage may be a high-frequency bias voltage. The plasma atmosphere of the processing space 111 may be formed and controlled by the first voltage applied to the bias electrode 123.

The first voltage application unit 140 may include a bias voltage generator 141 that generates the first voltage, a bias matcher 142, and a sensor 143.

The bias matcher 142 may be placed between the bias voltage generator 141 and the electrostatic chuck 120 to adjust the matching of the first voltage.

The sensor 143 is connected to the output terminal of the bias matcher 142, and the physical value output from the bias matcher 142 may be measured by the sensor 143. For example, a voltage value output from the bias matcher 142 may be measured by the sensor 143.

The second voltage application unit 150 may be electrically connected to the DC electrode 122 of the electrostatic chuck 120. The second voltage application unit 150 may apply a second voltage to the DC electrode 122 of the electrostatic chuck 120.

For example, the second voltage may be a DC voltage. Chucking force, which is an electrostatic force fixing a substrate (W) to the electrostatic chuck 120, may be generated by the second voltage applied to the DC electrode 122.

The second voltage application unit 150 may include a DC voltage generator 151 that generates the second voltage. The second voltage application unit 150 is disposed between the DC voltage generator 151 and the DC electrode 122, and may further include a switch for controlling whether to apply the second voltage.

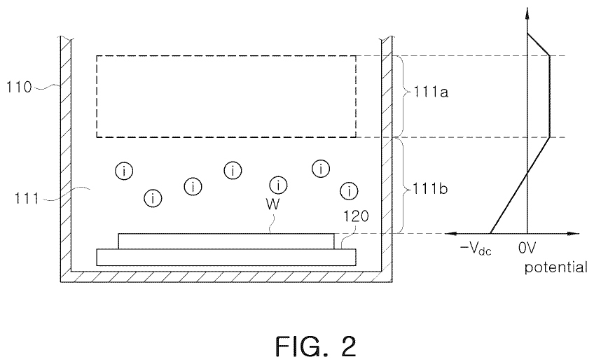

FIG. 2 is an example diagram illustrating a voltage drop phenomenon inside the sheath. Referring to FIG. 2, a substrate (W) is disposed on the electrostatic chuck 120 disposed in the chamber 110, and plasma may be generated in the processing space 111.

A plasma region 111a where a plasma bulk is located is formed in the upper portion of the processing space 111, and a sheath region 111b may be formed between the plasma region 111a and the electrostatic chuck 120.

Since positive ions are relatively densely packed in the sheath region 111b, a phenomenon of a sudden voltage drop may occur, as illustrated in the potential graph illustrated in FIG. 2.

Due to the voltage drop phenomenon in the sheath region 111b, the chucking force, which is the electrostatic force fixing the substrate (W) by the electrostatic chuck 120, may be lost. The loss of the chucking force may be estimated approximately as a DC bias value in relation to the second voltage applied to the DC electrode 122.

Referring again to FIG. 1, the compensation unit 160 may estimate the DC bias value according to the voltage drop inside the sheath and compensate for the loss of the chucking force based on the estimation result.

In detail, the compensation unit 160 may calculate a compensation value for the second voltage based on the measurement value of the sensor 143 disposed in the first voltage application unit 140. The compensation value for the second voltage may be a DC bias value.

The compensation unit 160 may estimate the voltage drop inside the sheath located between the electrostatic chuck 120 and the plasma region, based on the measurement value of the sensor 143. The compensation unit 160 may approximate the voltage drop inside the sheath by a DC bias value.

For example, the compensation unit 160 may measure a Vrms value of the output terminal of the bias matcher 142, using the sensor 143. The compensation unit 160 may calculate an approximate value of the DC voltage based on the Vrms value, as the compensation value for the second voltage. The compensation value for the second voltage may be calculated as, for example, a value that is √2 times the Vrms value.

For another example, the compensation unit 160 may measure the Vpp (Peak-to-Peak Voltage) value of the output terminal of the bias matcher 142, using the sensor 143. The compensation unit 160 may calculate the compensation value for the second voltage based on the Vpp value of the output terminal of the bias matcher 142.

The compensation unit 160 may compensate for the loss of the chucking force that occurs in the electrostatic chuck 120, based on the compensation value for the second voltage. The compensation unit 160 may transmit the compensation value for the second voltage to the DC voltage generator 151.

The compensation unit 160 may calculate the compensation value for the second voltage for each process step included in the substrate processing recipe, and transmit the compensation value for the second voltage for each process step to the DC voltage generator 151.

The DC voltage generator 151 may generate a voltage having a magnitude provided by adding the compensation value to a second voltage setting value of the substrate processing recipe.

For the bias voltage and DC voltage of an electrostatic chuck, which are operated independently, in the related art, in an embodiment of the present disclosure, the value output from a bias matcher that applies the bias voltage may be sensed to estimate the voltage drop inside the sheath, and the loss of the chucking force may be compensated therefrom.

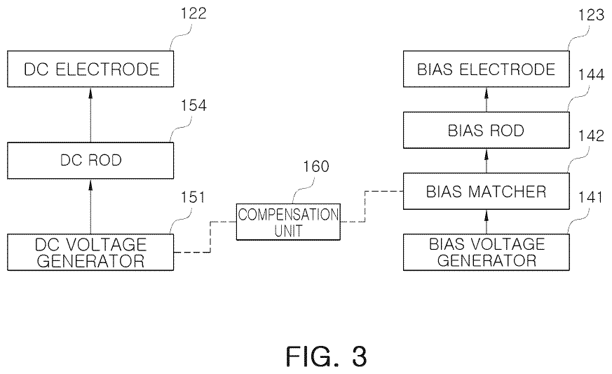

FIG. 3 is a block diagram illustrating a portion of the configuration of the apparatus 100 for processing a substrate. Referring to FIG. 3, the bias voltage for forming and controlling the plasma atmosphere of the processing space 111 may be applied to the bias electrode 123 of the electrostatic chuck 120 through the bias voltage generator 141, the bias matcher 142, and the bias ROD 144.

In addition, the DC voltage for generating the chucking force for fixing the substrate (W) to the electrostatic chuck 120 may be applied to the DC electrode 122 of the electrostatic chuck 120 through the DC voltage generator 151 and the DC ROD 154.

The compensation unit 160 may transmit a compensation value for the second voltage to the DC voltage generator 151 based on the measured value of the sensor 143 disposed at the output terminal of the bias matcher 142.

In detail, in an embodiment of the present disclosure, the voltage drop inside the sheath may be estimated, by which an approximate value is calculated with a DC bias value, to be applied as a compensation value for the DC voltage, thereby compensating for the loss of the chucking force in real time.

Therefore, in the apparatus for and method of processing a substrate according to an embodiment of the present disclosure, the risk of the substrate's settling position changing for each substrate processing process or each step included in each process may be reduced, and the effect of improving the accuracy of substrate processing may be obtained.

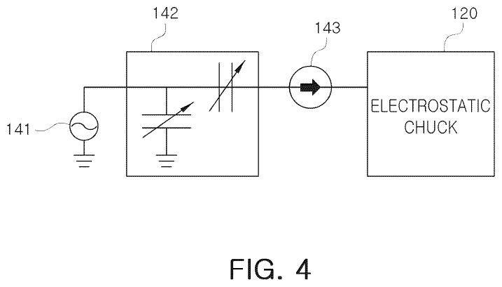

FIG. 4 illustrates a partial configuration of an apparatus 100 for processing a substrate according to an embodiment. As illustrated in FIG. 4, the bias matcher 142 may include a circuit including two capacitor elements.

The sensor 143 may be connected to the output terminal of the bias matcher 142. For example, the Vrms value or Vpp value of the output terminal of the bias matcher 142 may be measured using the sensor 143.

In an embodiment, the voltage drop inside the sheath may be estimated based on the measured value of the sensor 143. The voltage drop inside the sheath may be approximated by the DC bias value.

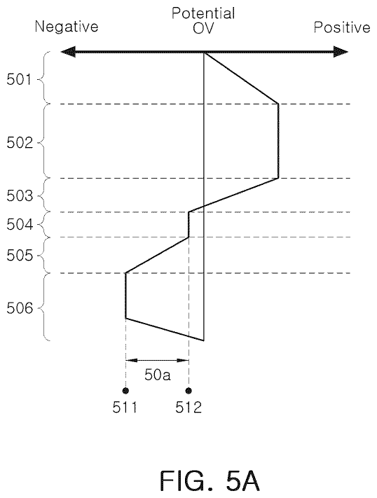

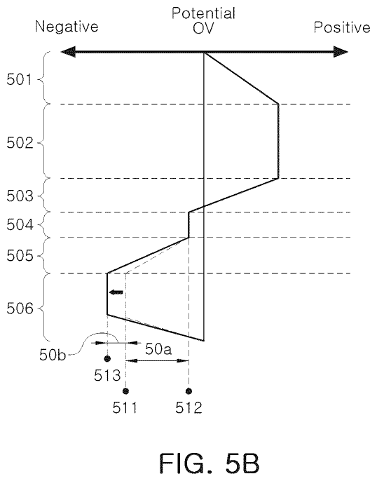

FIG. 5A is a graph illustrating potentials by location of an apparatus for processing a substrate according to a comparative example, and FIG. 5B is a graph illustrating potentials by location of an apparatus for processing a substrate according to an embodiment of the present disclosure.

In FIGS. 5A and 5B, potentials of a chassis ground region 501, a plasma region 502, a sheath region 503, a substrate region 504, an electrostatic chuck region 505, and a DC voltage generator region 506 are illustrated by region.

In the comparative example illustrated in FIG. 5A, a voltage corresponding to a DC voltage setting value 511 according to a substrate processing recipe is generated in the DC voltage generator region 506, but chucking force loss occurs in the electrostatic chuck region 505 due to a voltage drop inside the sheath. The voltage drop inside the sheath may be approximated by the DC bias value 512.

In comparison therewith, referring to FIG. 5B, in the apparatus 100 for processing a substrate according to the present disclosure, a voltage corresponding to a DC voltage setting value 511 according to a substrate processing recipe and a voltage corresponding to a compensation value 50b for compensating for chucking force loss may be additionally generated in the DC voltage generator region 506.

Therefore, in the DC voltage generator region 506, a voltage 513 corresponding to a value that is the sum of the voltage corresponding to the DC voltage setting value 511 according to a substrate processing recipe and the compensation value 50b may be generated.

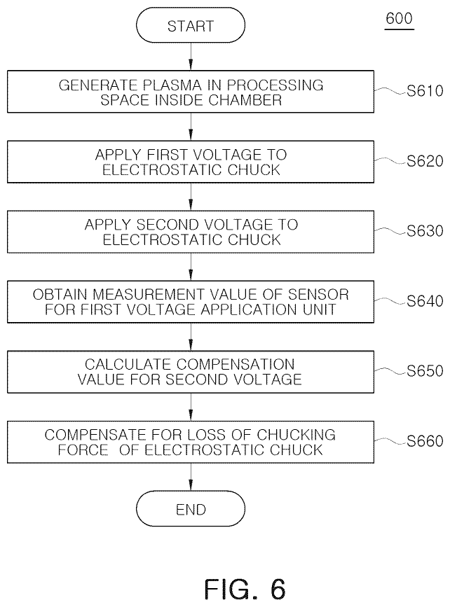

FIG. 6 is a flowchart of a method of processing a substrate according to an embodiment. Referring to FIG. 6, a method (600) of processing a substrate may include an operation (S610) of generating plasma in a processing space inside a chamber, an operation (S620) of applying a first voltage to an electrostatic chuck, an operation (S630) of applying a second voltage to an electrostatic chuck, an operation (S640) of obtaining a measurement value of a sensor for a first voltage application unit, an operation (S650) of calculating a compensation value for the second voltage, and an operation (S660) of compensating for loss of chucking force of the electrostatic chuck.

In the operation (S620) of applying the first voltage, the first voltage may be a high-frequency bias voltage.

In the operation (S630) of applying the second voltage, the second voltage may be a DC voltage. Chucking force, which is an electrostatic force fixing the substrate, may be generated by applying a second voltage to the electrostatic chuck.

The operation (S640) of obtaining a measurement value of a sensor for the first voltage application unit may include an operation of measuring a physical value of an output terminal of a bias matcher. For example, a Vrms value or a Vpp value output from a bias matcher may be measured.

The operation (S650) of calculating the compensation value for the second voltage may include an operation of estimating the voltage drop inside the sheath located between the electrostatic chuck and the plasma region.

In the operation (S650) of calculating the compensation value for the second voltage, a value that is √2 times the Vrms value measured in operation (S640) may be calculated as the compensation value.

The operation (S660) of compensating for the loss of the chucking force of the electrostatic chuck may further include an operation of transmitting the compensation value calculated in operation (S650) to a second voltage generator that generates the second voltage.

Operations S610 to S660 may be performed for each process step included in the substrate processing recipe. Therefore, the compensation value for the second voltage may be calculated for each process step included in the substrate processing recipe.

The operation (S660) of compensating for the loss of the chucking force of the electrostatic chuck may further include an operation of generating a second voltage having a magnitude that is the sum of the compensation value calculated in operation (S650) and the second voltage setting value of the substrate processing recipe.

In addition, in describing the present disclosure, ‘˜ part,’ ‘portion,’ ‘member,’ or ‘unit’ may be implemented in various manners, for example, by a processor, program instructions executed by a processor, a software module, a microcode, a computer program product, a logic circuit, an application-specific integrated circuit, firmware, or the like.

The contents of the method disclosed in the embodiment of the present disclosure may be directly implemented by a hardware processor, or may be implemented and performed by a combination of hardware and software modules among the processors. The software module may be stored in a storage medium of the related art, such as a random access memory, a flash memory, a read-only memory, a programmable read-only memory, an electrically erasable programmable memory, a register, and the like. The storage medium is located in the memory, and the processor reads the information stored in the memory and combines the information with the hardware to complete the contents of the above-described method. To avoid duplication, a detailed description is omitted here.

In the implementation process, each content of the above-described method may be completed by a logical integrated circuit of the hardware among the processors or an instruction in the form of software.

For example, those skilled in the art will recognize that each illustrative unit and algorithm step described in the embodiments disclosed herein may be obtained by combining electronic hardware or a combination of computer software and electronic hardware. Whether such a function is performed in a hardware manner or in a software manner is determined by the specific application and design constraints of the technical solution. Those skilled in the art may implement the described function using different methods for respective specific applications, but such implementation should not be considered as being outside the scope of the present disclosure.

In some embodiments provided in the present disclosure, it should be understood that the disclosed devices and methods may be obtained in other manners. For example, the device embodiments described above are merely examples, and for example, the division of the units is merely a kind of logical functional division, and other division methods may exist in actual implementation. For example, multiple units or assemblies may be combined or integrated into another system, or some features may be ignored or not performed. On the other hand, the coupling or direct coupling or communication connection between each other illustrated or discussed may be an indirect coupling or communication connection through some interface, device or unit, and may be electrical, mechanical or other forms.

The units described as separate components above may be physically separate, and the components illustrated as units may or may not be physical units, for example, may be located in one place or distributed in multiple network units. Some or all of the units may be selected according to actual needs to implement the solution of the present embodiment.

For example, respective functional units in respective embodiments of the present disclosure may be integrated into one processing unit, each unit may exist alone, or two or more units may be integrated into one unit.

If the above function is implemented in the form of a software functional unit and sold or used as an independent product, the function may be stored in one computer-readable storage medium. Based on this understanding, the technical solution of the present disclosure, which is essential or contributes to the prior art, or a part of the technical solution, may be implemented in the form of a software product, and the computer software product is stored in one storage medium and includes a few instructions to cause one computer device (which may be a personal computer, a server, a network device, or the like) to perform all or part of the operations of the method described in each embodiment of the present disclosure. The storage medium described above includes various media capable of storing program codes, such as a USB memory, a mobile hard disk, a read-only memory (ROM), a random access memory (RAM), a magnetic disk, a CD-ROM, or the like.

As set forth above, according to an embodiment, there are provided an apparatus for and a method of processing a substrate, in which loss of chucking force of an electrostatic chuck due to voltage drop inside a sheath may be compensated.

In an embodiment, there are provided an apparatus for and a method of processing a substrate, in which loss of chucking force of an electrostatic chuck due to voltage drop inside a sheath is approximated by a DC bias value and the DC bias value may be derived based on a measurement value of a sensor connected to an output terminal of a bias matcher that applies a bias voltage to the electrostatic chuck.

In an embodiment, there are provided an apparatus for and a method of processing a substrate in which risk of the substrate's mounting position changing for each substrate processing process or each process step may be prevented and the accuracy of the process may be improved.

While example embodiments have been illustrated and described above, it will be apparent to those skilled in the art that modifications and variations could be made without departing from the scope of the present disclosure as defined by the appended claims.

What is claimed is:

1. An apparatus for processing a substrate, comprising:
a chamber having a processing space therein;
an electrostatic chuck supporting a substrate within the chamber;
a plasma generating unit generating plasma in the processing space;
a first voltage application unit applying a first voltage to the electrostatic chuck;
a second voltage application unit applying a second voltage to the electrostatic chuck; and
a compensation unit calculating a compensation value for the second voltage based on a measurement value of a sensor disposed in the first voltage application unit, and compensating for loss of chucking force generated in the electrostatic chuck based on the compensation value for the second voltage.

2. The apparatus of claim 1, wherein the first voltage is a high-frequency bias voltage, and
the second voltage is a DC voltage generating the chucking force fixing the substrate to the electrostatic chuck.

3. The apparatus of claim 2, wherein the first voltage application unit includes a first voltage generator generating the first voltage, and a bias matcher disposed between the first voltage generator and the electrostatic chuck, and
the sensor is connected to an output terminal of the bias matcher.

4. The apparatus of claim 3, wherein the compensation unit estimates a voltage drop inside a sheath located between the electrostatic chuck and a plasma region based on a measurement value of the sensor.

5. The apparatus of claim 4, wherein the compensation unit measures a Vrms value of the output terminal of the bias matcher, using the sensor.

6. The apparatus of claim 5, wherein the compensation unit calculates a direct current (DC) voltage approximation based on the Vrms value, as the compensation value.

7. The apparatus of claim 4, wherein the compensation unit measures a Peak-to-Peak Voltage (Vpp) value of the output terminal of the bias matcher, using the sensor.

8. The apparatus of claim 2, wherein the second voltage application unit includes a second voltage generator generating the second voltage, and
the compensation unit transmits the compensation value to the second voltage generator.

9. The apparatus of claim 8, wherein the compensation unit calculates the compensation value for each process step included in a substrate processing recipe, and
the second voltage generator generates a voltage having a magnitude provided by adding the compensation value to a second voltage setting value of the substrate processing recipe.

10. A method of processing a substrate, comprising:
generating plasma in a processing space within a chamber;
applying a first voltage to an electrostatic chuck supporting a substrate within the chamber;
applying a second voltage to the electrostatic chuck;
obtaining a measurement value of a sensor for a first voltage application unit applying the first voltage;
calculating a compensation value for the second voltage based on the measurement value of the sensor; and
compensating for loss of chucking force of the electrostatic chuck based on the compensation value for the second voltage.

11. The method of claim 10, wherein the first voltage is a high-frequency bias voltage, and
the second voltage is a DC voltage generating the chucking force fixing the substrate to the electrostatic chuck.

12. The method of claim 11, wherein the first voltage application unit includes a first voltage generator generating the first voltage, and a bias matcher disposed between the first voltage generator and the electrostatic chuck, and
the obtaining the measurement value of the sensor includes measuring an output terminal of the bias matcher using the sensor.

13. The method of claim 12, wherein the calculating the compensation value for the second voltage includes estimating a voltage drop inside a sheath located between the electrostatic chuck and a plasma region, I based on the measurement value of the sensor.

14. The method of claim 13, wherein the obtaining the measurement value of the sensor further includes obtaining a Vrms value output from the bias matcher.

15. The method of claim 14, wherein the calculating the compensation value for the second voltage includes calculating a DC voltage approximation based on the Vrms value, as the compensation value.

16. The method of claim 13, wherein the obtaining the measurement value of the sensor further includes obtaining a Vpp value output from the bias matcher.

17. The method of claim 11, wherein the compensating for the loss of the chucking force of the electrostatic chuck includes transmitting the compensation value to a second voltage generator generating the second voltage.

18. The method of claim 17, wherein the calculating the compensation value for the second voltage includes calculating the compensation value for each process step included in a substrate processing recipe, and
the compensating for the loss of the chucking force of the electrostatic chuck further includes generating a second voltage having a magnitude that is a sum of the compensation value and a second voltage setting value of the substrate processing recipe.

19. An apparatus for processing a substrate, comprising:
a chamber having a processing space therein;
a substrate support member including an electrostatic chuck supporting a substrate and adsorbing the substrate, within the chamber;
a plasma generation unit supplying processing gas to the processing space and generating plasma from the processing gas;
a bias voltage application unit including a bias voltage generator generating a bias voltage and applying the bias voltage to a first electrode of the electrostatic chuck;
a DC voltage application unit including a DC voltage generator generating a DC voltage and applying the DC voltage to a second electrode of the electrostatic chuck; and
a compensation unit calculating a compensation value for the DC voltage, based on a measurement value of a sensor disposed in the bias voltage application unit, and compensating for loss of chucking force for adsorbing the substrate by the electrostatic chuck based on the compensation value for the DC voltage.

20. The apparatus of claim 19, wherein the bias voltage application unit further includes a bias matcher disposed between the bias voltage generator and the electrostatic chuck,
the sensor is connected to an output terminal of the bias matcher, and
the compensation unit measures a Vrms value of the output terminal of the bias matcher using the sensor, and calculates a DC voltage approximation based on the Vrms value, as the compensation value.
